(19) United States
(12) Patent Application Publication
(10) Pub. No.: US 2026/0293735 A1
(43) Pub. Date: Sep. 24, 2026

(54) PROTECTIVE FILM FORMING METHOD AND CHIP MANUFACTURING METHOD

(71) Applicant: DISCO CORPORATION, Tokyo (JP)

(72) Inventors: Akihiro Hirata, Tokyo (JP); Takumi Shingu, Tokyo (JP); Sho Osawa, Tokyo (JP); Senichi Ryo, Tokyo (JP); Tomoaki Endo, Tokyo (JP)

(21) Appl. No.: 19/555,157

(22) Filed: Mar. 3, 2026

(30) Foreign Application Priority Data
Mar. 24, 2025 (JP) 2025-048410
Dec. 15, 2025 (JP) 2025-249607

(51) Int. Cl. H10W 72/00; H10P 58/00

(52) U.S. Cl. CPC H10W 72/01215; H10P 58/00

(57) ABSTRACT

Provided is a protective film forming method of forming a protective film on a target object, the method including holding a reverse side of the target object on a holding table such that a face side of the target object is exposed, and forming a protective film on the face side of the target object, in which the forming the protective film includes supplying a protective film agent in liquid form to the face side of the target object, rotating the holding table, and supplying gas to the face side of the target object.

### BACKGROUND OF THE INVENTION

### Field of the Invention

The present invention relates to a protective film forming method of forming a protective film on a target object and a chip manufacturing method of dividing a target object into a plurality of chips.

### Description of the Related Art

In a manufacturing process of device chips, a wafer having devices formed in a plurality of respective regions demarcated by a plurality of projected dicing lines (streets) crossing each other is used. Dividing this wafer along the projected dicing lines allows device chips including devices to be obtained. The device chips are incorporated in various electronic appliances such as mobile telephones and personal computers.

To divide the wafer, a cutting apparatus that cuts the wafer by an annular cutting blade is used. In addition, in recent years, a process of dividing the wafer by laser processing is also under development. For example, when a laser beam is applied to the wafer along the projected dicing lines to apply ablation processing to the wafer, the wafer is divided along the projected dicing lines. Using laser processing allows high processing speed to be set compared to a case where the wafer is cut by a cutting blade, thus improving the processing efficiency. Further, laser processing can also be applied to, for example, hard wafers that are difficult to cut by a cutting blade.

When laser processing is applied to the wafer, processing swarf such as a solidified melt (debris) is generated at a region of the wafer irradiated with the laser beam. When this processing swarf adheres to the wafer or a device, the wafer or the device would be contaminated, and the device chips may have lower quality. In view of this, a method of covering the wafer with a protective film at the time of laser processing is proposed. For example, a protective film agent in liquid form is supplied to the wafer that has not yet been subjected to laser processing, and a protective film is formed by spin coating (see Japanese Patent Laid-open No. 2004-188475 and Japanese Patent Laid-open No. 2004-322168). Covering the wafer with a protective film can prevent processing swarf generated at the time of laser processing from adhering to the wafer or the device.

### SUMMARY OF THE INVENTION

As described above, in applying laser processing to a target object such as a wafer, a face side of the target object is preferably covered with a protective film. However, in the case of forming a protective film on the face side of the target object by spin coating, the protective film agent supplied to the target object does not dry well, requiring a long period of time for forming the protective film, in some cases. Moreover, the protective film agent not drying well may sometimes cause difficulty in forming the protective film having a certain thickness or more.

Further, the face side of a target object is not necessarily flat and may have protrusions (protruding portions) formed thereon. For example, in a case where the target object is a wafer having a plurality of devices, bumps each functioning as a connection electrode may in some cases be connected to respective devices and serving as protrusions protruding from the face side of the wafer. When spin coating is used to form a protective film on the face side of the target object having protrusions, a protective film agent in liquid form is supplied to the face side and the protrusions of the target object. However, the protective film agent in liquid form supplied to the protrusions is highly likely to flow down from the protrusions and enter gaps between the protrusions. Hence, a protective film having a sufficient thickness is less likely to be formed on the protrusions, and especially, distal end portions of the protrusions are highly likely to be exposed without being covered with the protective film. This could result in a situation where adhering of processing swarf to the protrusions is not appropriately blocked by the protective film.

The present invention has been made in view of the problems described above, and has an object to provide a protective film forming method and a chip manufacturing method that can appropriately form a protective film on a target object.

In accordance with an aspect of the present invention, there is provided a protective film forming method of forming a protective film on a target object, including holding a reverse side of the target object on a holding table such that a face side of the target object is exposed, and forming the protective film on the face side of the target object, in which the forming the protective film includes supplying a protective film agent in liquid form to the face side of the target object, rotating the holding table, and supplying gas to the face side of the target object.

Note that the supplying the protective film agent, the rotating the holding table, and the supplying the gas may be carried out at different timings. Moreover, at least two or more of the supplying the protective film agent, the rotating the holding table, and the supplying the gas may be carried out concurrently.

Further, a rotational speed of the holding table may be equal to or lower than 1000 rpm. Further, the target object may have protrusions on the face side. Further, the protrusions may each be a bump provided on the target object.

In accordance with another aspect of the present invention, there is provided a chip manufacturing method of dividing a target object demarcated into a plurality of regions by projected dicing lines into a plurality of chips, including holding a reverse side of the target object on a holding table such that a face side of the target object is exposed, forming a protective film on the face side of the target object, and dividing the target object into the plurality of chips by applying a laser beam from the face side of the target object to form laser processing grooves in the face side of the target object along the projected dicing lines and exposing the laser processing grooves on the reverse side of the target object, in which the forming the protective film includes supplying a protective film agent in liquid form to the face side of the target object, rotating the holding table, and supplying gas to the face side of the target object.

In accordance with a further aspect of the present invention, there is provided a chip manufacturing method of dividing a target object demarcated into a plurality of regions by projected dicing lines into a plurality of chips, including holding a reverse side of the target object on a holding table such that a face side of the target object is exposed, forming a protective film on the face side of the target object, and dividing the target object into the plurality of chips by supplying plasma etching gas to the target object via the protective film after removing the protective film along the projected dicing lines, in which the forming the protective film includes supplying a protective film agent in liquid form to the face side of the target object, rotating the holding table, and supplying gas to the face side of the target object.

Note that the supplying the protective film agent, the rotating the holding table, and the supplying the gas may be carried out at different timings. Moreover, at least two or more of the supplying the protective film agent, the rotating the holding table, and the supplying the gas may be carried out concurrently.

Further, a rotational speed of the holding table may be equal to or lower than 1000 rpm. Further, the target object may have protrusions on the face side. Further, the protrusions may each be a bump provided on the target object.

In the protective film forming method and the chip manufacturing method according to one aspect of the present invention, gas is supplied to the face side of the target object when a protective film is to be formed on the target object. This promotes drying of the protective film agent, making it possible to form the protective film having a sufficient thickness in a short period of time.

Further, in the protective film forming method and the chip manufacturing method according to the aspect of the present invention, gas may be supplied while a protective film agent is supplied to the face side of the target object having protrusions, to dry the protective film agent and form the protective film. This makes it possible to form the protective film having a thickness sufficient for covering the protrusions and reliably prevent processing swarf from adhering to the protrusions by the protective film.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view illustrating a target object;

FIG. 1B is a front view illustrating the target object;

FIG. 2 is a perspective view illustrating the target object supported by a frame;

FIG. 3 is a flowchart illustrating a chip manufacturing method;

FIG. 4 is a front view, partly in cross section, illustrating the target object in a holding step and a protective film forming step;

FIG. 5 is a front view, partly in cross section, illustrating the target object on which a protective film is formed;

FIG. 6 is a front view, partly in cross section, illustrating the target object in a dividing step; and

FIG. 7 is a front view, partly in cross section, illustrating the target object in which a laser processing groove is formed.

### DETAILED DESCRIPTION OF THE PREFERRED EMBODIMENT

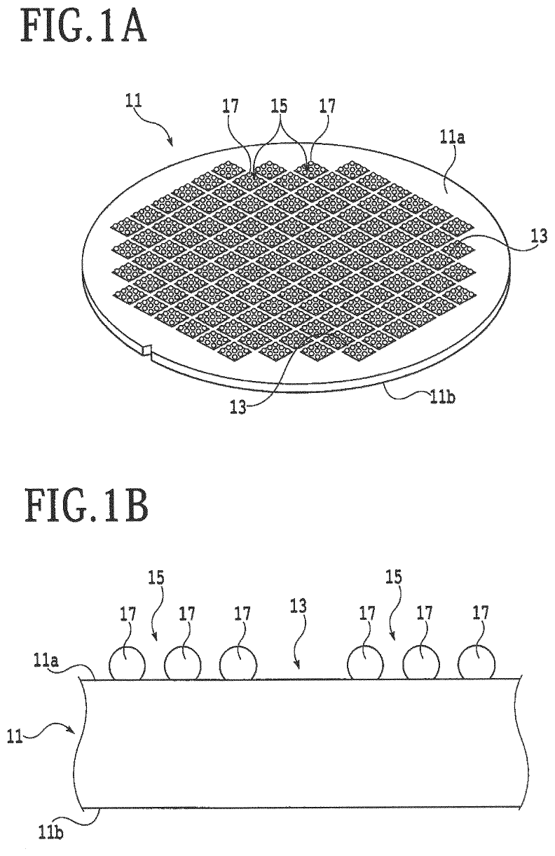

An embodiment according to one aspect of the present invention will hereinafter be described with reference to the accompanying drawings. First, a configuration example of a target object on which a protective film can be formed by a protective film forming method according to the present embodiment will be described. FIG. 1A is a perspective view illustrating the target object denoted by 11, while FIG. 1B is a front view illustrating the target object 11.

As described later, the target object 11 is subjected to laser processing after a protective film is formed thereon. That is, the target object 11 corresponds to a protective film formed object on which a protective film is formed and a workpiece to be subjected to laser processing. For example, the target object 11 is a disk-shaped wafer (substrate) formed of a semiconductor material such as single crystal silicon and has a face side (first side) 11a and a reverse side (second side) 11b that are substantially parallel to each other.

The face side 11a of the target object 11 is demarcated into a plurality of rectangular regions by a plurality of projected dicing lines (streets) 13 arrayed in a grid pattern to cross one another. Further, in the plurality of regions demarcated by the projected dicing lines 13, devices 15 such as integrated circuits (ICs), large scale integration (LSI) circuits, light emitting diodes (LEDs), and micro electro mechanical systems (MEMS) are formed. The target object 11 is divided along the projected dicing lines 13 to manufacture a plurality of chips (device chips) each including the device 15.

Yet, there are no limitations on the material, shape, structure, size, and the like of the target object 11. For example, the target object 11 may be a wafer (substrate) formed of a semiconductor (GaAs, Sic, InP, Gan, etc.) other than silicon, sapphire, glass, ceramics, resin, metal, or the like. Further, there are also no limitations on the kind, quantity, shape, structure, size, layout, and the like of the devices 15.

On the face side 11a of the target object 11, a plurality of protrusions (protruding portions) 17 are formed. For example, each of the protrusions 17 is a bump (connection electrode) connected to each of the plurality of respective devices 15 and is protruding from a face side of the device 15. A bump is a spherical electrode made of a metal material such as solder and is connected to the electrode, terminal, and the like included in the device 15. With the bumps being connected to the devices 15, the plurality of protrusions 17 are formed on the face side 11a of the target object 11. Note that the height of each bump is set as appropriate according to the structure and the like of the devices 15 and is, for example, equal to or greater than 10 μm but equal to or smaller than 500 μm.

Yet, the protrusions present on the face side 11a of the target object 11 are not limited to such bumps. For example, protrusions may be formed on the face side 11a of the target object 11 due to the presence or absence of the devices 15 or the structure of the devices 15. Moreover, such structures as test element groups (TEGs) used for testing the devices 15 may be formed on the projected dicing lines 13 of the target object 11. In this case, the structures on the projected dicing lines 13 may also become protrusions protruding from the face side 11a of the target object 11. Moreover, the target object 11 may be free of protrusions such as bumps.

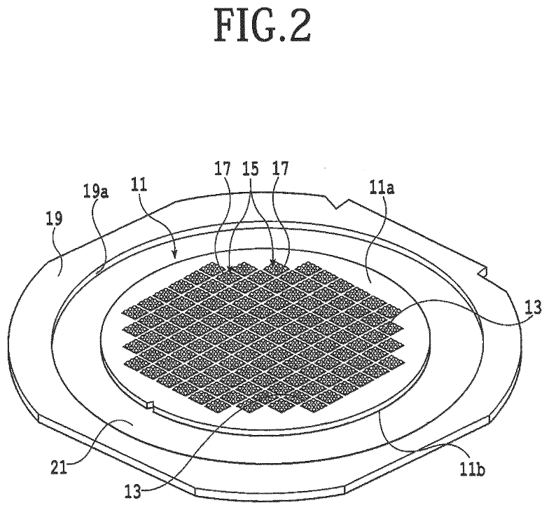

FIG. 2 is a perspective view illustrating the target object 11 supported by a frame 19. In the present embodiment, after a protective film is formed on the target object 11 including the protrusions 17, the target object 11 is subjected to laser processing. In this instance, for the convenience of handling (transfer, holding, and the like) of the target object 11, the target object 11 is supported by the frame 19 having an annular shape.

The frame 19 is an annular member made of metal such as stainless steel (SUS), and has a central portion in which a circular-shaped opening 19a penetrating the frame 19 in a thickness direction is provided. Note that a diameter of the opening 19a is greater than that of the target object 11.

To the target object 11 and the frame 19, a circular sheet 21 is fixed. The sheet 21 is a tape, for example, including a circular film-shaped base and an adhesive layer (glue layer) disposed on the base. The base is made of resin such as polyolefin, polyvinyl chloride, or polyethylene terephthalate, for example, whereas the adhesive layer is made of an epoxy-based, acryl-based, or rubber-based adhesive, for example. Yet, the sheet 21 may be a thermocompression bonding sheet that has no adhesive layer and that can be thermocompression-bonded to the target object 11 and the frame 19.

In a state in which the target object 11 is arranged inside the opening 19a of the frame 19, a central portion of the sheet 21 is affixed to the reverse side 11b of the target object 11, while an outer peripheral portion of the sheet 21 is affixed to the frame 19. The target object 11 is thereby supported by the frame 19 via the sheet 21.

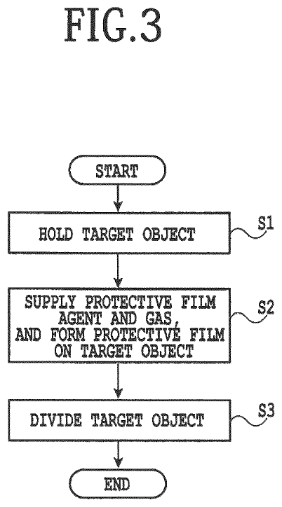

Next, a protective film forming method and a chip manufacturing method according to the present embodiment are described. FIG. 3 is a flowchart illustrating the chip manufacturing method. In the present embodiment, first, the target object 11 is held on a holding table (holding step S1), and then, a protective film agent and gas are supplied to the target object 11 to form a protective film thereon (protective film forming step S2). Thereafter, the target object 11 on which the protective film is formed is processed to be divided into a plurality of chips (dividing step S3). Note that the holding step S1 and the protective film forming step S2 correspond to the protective film forming method according to the present embodiment.

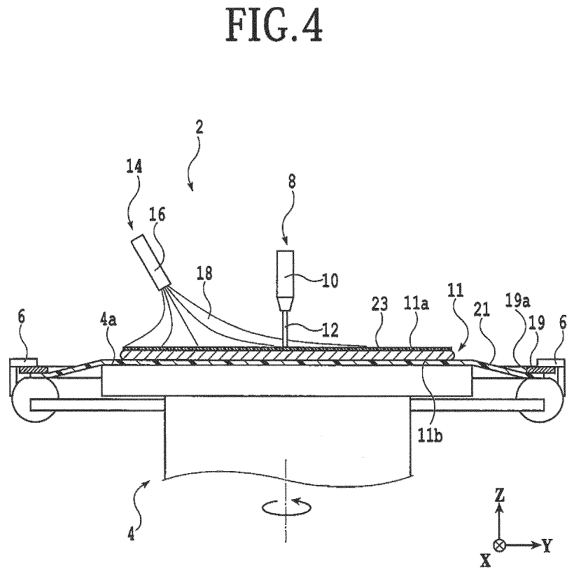

FIG. 4 is a front view, partly in cross section, illustrating the target object 11 in the holding step S1 and the protective film forming step S2. In forming the protective film on the target object 11, for example, a protective film forming apparatus (protective film forming unit) 2 illustrated in FIG. 4 is used. Note that an X-axis direction (first horizontal direction) and a Y-axis direction (second horizontal direction) are directions perpendicular to each other. In addition, a Z-axis direction (an upward-downward direction, a height direction, or a vertical direction) is a direction perpendicular to the X-axis direction and the Y-axis direction. In the present embodiment, a case where the face side 11a of the target object 11 is the surface (formed surface) on which the protective film is formed is described.

The protective film forming apparatus 2 includes a holding table (chuck table) 4 that holds the target object 11. The holding table 4 has an upper surface that is a flat surface substantially parallel to a horizontal plane (XY plane) and that constitutes a holding surface 4a which holds the target object 11. The holding surface 4a is connected to a suction source (not illustrated) such as an ejector via a fluid channel (not illustrated) formed inside the holding table 4, a valve, and the like, for example.

The holding table 4 is a spinner table that is rotatable in a state of holding the target object 11. Specifically, to the holding table 4, a rotational drive source (not illustrated) such as a motor that rotates the holding table 4 about a rotational axis substantially parallel to the Z-axis direction is coupled. Moreover, around the holding table 4, a plurality of clamps 6 for gripping and securing the frame 19 supporting the target object 11 are provided.

Further, the protective film forming apparatus 2 includes a protective film agent supply unit 8 that supplies the protective film agent as the material of the protective film. For example, the protective film agent supply unit 8 includes a protective film agent supply nozzle 10 that supplies a protective film agent 12 in liquid form to the target object 11, and the protective film agent supply nozzle 10 is disposed above the holding table 4. The protective film agent 12 is supplied from a supply port of the protective film agent supply nozzle 10 toward the target object 11 held on the holding table 4.

The protective film agent 12 is manufactured by solute being dissolved in solvent. For example, water and an organic solvent are used as the solvent, and water-soluble resin and a laser light absorbent are used as the solute. Examples of the organic solvent include methyl alcohol, ethyl alcohol, isopropyl alcohol, ester, alkylene glycol monoalkyl ether, alkylene glycol, alkylene glycol monoalkyl ether acetate, or the like. Note that, as alkylene glycol monoalkyl ether, propylene glycol monomethyl ether (PGME) is particularly preferably used. Examples of the water-soluble resin include polyvinyl alcohol (PVA), polyvinylpyrrolidone (PVP), hydroxypropyl cellulose, polyethylene glycol, polyethylene oxide, methyl cellulose, ethyl cellulose, polyacrylic acid, poly-N-vinylacetamide, polystyrene sulfonate, special nylon, phenolic resin, melamine formaldehyde resin, polyglycerin, or the like. Moreover, as the water-soluble resin, a graft polymer of the abovementioned kinds of resin may also be used. Examples of the laser light absorbent include cinnamic acid-based compounds such as ferulic acid and caffeic acid, benzophenone-based compounds such as hydroxybenzophenone and 2-hydroxy-4-methoxybenzophenone-5-sulfonic acid, anthraquinone-based compounds such as carminic acid, flavonoid compounds such as α-glucosyl rutin, and the like.

Further, the protective film forming apparatus 2 includes a gas supply unit 14 that supplies gas to the protective film agent 12 supplied to the target object 11. For example, the gas supply unit 14 includes a gas supply nozzle 16 that supplies gas 18 such as air toward the target object 11 held on the holding table 4, and the gas supply nozzle 16 is disposed above the holding table 4. By the gas 18 being blown from a supply port of the gas supply nozzle 16 against the protective film agent 12 supplied to the face side 11a of the target object 11, drying of the protective film agent 12 is promoted, making it easier to form a protective film having a certain thickness or more on the target object 11.

The spin coating using the abovementioned protective film forming apparatus 2 forms a protective film on the target object 11. Specifically, first, the reverse side 11b of the target object 11 is held on the holding table 4 such that the face side 11a of the target object 11 is exposed (holding step S1). In the holding step S1, the target object 11 is arranged on the holding surface 4a of the holding table 4 such that the face side 11a (formed surface side) is exposed upward and the reverse side 11b (sheet 21 side) faces the holding surface 4a. In addition, the frame 19 is secured by the plurality of clamps 6. When suction force (negative pressure) of the suction source is caused to act on the holding surface 4a in this state, the target object 11 is held under suction on the holding table 4 via the sheet 21.

Next, the protective film agent 12 and the gas 18 are supplied to the target object 11 to form a protective film 23 (protective film forming step S2). The protective film forming step S2 includes a first step of supplying the protective film agent 12 in liquid form to the face side 11a of the target object 11, a second step of rotating the holding table 4, and a third step of supplying the gas 18 to the face side 11a of the target object 11.

Specifically, first, a positional relation between the holding table 4 and the protective film agent supply nozzle 10 is adjusted such that the protective film agent supply nozzle 10 overlaps the rotational axis (center of the holding surface 4a) of the holding table 4. For example, to the protective film agent supply nozzle 10, a swing arm (not illustrated) that swings the protective film agent supply nozzle 10 along the XY plane is coupled. By being swung by the swing arm, the protective film agent supply nozzle 10 is positioned directly above the rotational axis of the holding table 4.

Further, a positional relation between the holding table 4 and the gas supply nozzle 16 is adjusted such that the gas 18 can be supplied from the gas supply nozzle 16 toward the face side 11a of the target object 11. For example, in a case where the gas supply nozzle 16 is movable, the gas supply nozzle 16 is located at a position that is above the target object 11 and where the gas supply nozzle 16 does not overlap the protective film agent supply nozzle 10. Yet, the gas supply nozzle 16 may be fixed to a predetermined position in advance such that the supply port of the gas supply nozzle 16 faces the face side 11a of the target object 11 held on the holding table 4.

Next, the first through third steps are carried out in a desired order. For example, first, the protective film agent 12 in liquid form is supplied from the supply port of the protective film agent supply nozzle 10 to the face side 11a of the target object 11 (first step). As a result, the protective film agent 12 is applied to a central portion of the target object 11. Next, the holding table 4 holding the target object 11 is rotated (second step). This makes the protective film agent 12 flow radially toward an outer peripheral edge from the central portion of the target object 11 by centrifugal force of the rotating target object 11. Consequently, the protective film agent 12 spreads over the entire face side 11a of the target object 11, and covers the face side 11a of the target object 11.

Note that the rotational speed of the holding table 4 is preferably set to a speed equal to or lower than a constant speed such that the protective film agent 12 supplied to the target object 11 does not excessively scatter. For example, the rotational speed of the holding table 4 in the second step is set to a speed equal to or lower than 1000 rpm.

Subsequently, the gas 18 is supplied from the supply port of the gas supply nozzle 16 to the face side 11a of the target object 11 in a state in which the holding table 4 is kept being rotated (third step). As a result, the gas 18 is blown against the protective film agent 12 applied along the face side 11a of the target object 11, promoting drying of the protective film agent 12. Consequently, the protective film agent 12 cures in a state of maintaining a certain thickness or more, and the protective film 23 is formed on the face side 11a of the target object 11.

As described above, in a case of supplying the gas 18 to the target object 11 while rotating the holding table 4 after supplying the protective film agent 12 to the target object 11, the second step and the third step are carried out concurrently after the first step. Yet, the order of performing the first step, the second step, and the third step can be set as desired. For example, supply of the protective film agent 12 (first step) and supply of the gas 18 (third step) may be carried out after rotation of the holding table 4 is started (second step). In this case, the gas 18 may be supplied after the protective film agent 12 is supplied, or the protective film agent 12 and the gas 18 may be supplied simultaneously.

Moreover, the timing of carrying out each of the first step, the second step, and the third step can also be set as desired. Specifically, the first step, the second step, and the third step may be carried out at different timings, or at least two or more of the first step, the second step, and the third step may be carried out concurrently.

For example, the holding table 4 is rotated after the protective film agent 12 is supplied to the face side 11a of the target object 11, to cover the face side 11a of the target object 11 with the protective film agent 12. Thereafter, the rotation of the holding table 4 is stopped, and the gas 18 is supplied to the face side 11a of the target object 11. In this case, the first through third steps are carried out in order at different timings.

Alternatively, the protective film agent 12 may be supplied to the face side 11a of the target object 11 while the holding table 4 is being rotated. Thereafter, the rotation of the holding table 4 may be stopped, and the gas 18 may be supplied to the face side 11a of the target object 11. In this case, after the first and second steps are carried out concurrently, the third step is performed.

As another alternative, the protective film agent 12 and the gas 18 may be supplied to the face side 11a of the target object 11 while the holding table 4 is being rotated. In this case, the first step and the second step are carried out concurrently, and the second step and the third step are also carried out concurrently. Further, by the protective film agent 12 and the gas 18 being supplied simultaneously, the first step, the second step, and the third step are carried out concurrently.

An example of the procedure of carrying out the first and second steps concurrently and also carrying out the second and third steps concurrently is as follows. The protective film agent 12 in liquid form is supplied from the supply port of the protective film agent supply nozzle 10 to the face side 11a of the target object 11 in a state in which the holding table 4 holding the target object 11 is being rotated. As a result, the protective film agent 12 is applied to the central portion of the target object 11, and flows radially toward the outer peripheral edge from the central portion of the target object 11 by the centrifugal force of the rotating target object 11. Consequently, the protective film agent 12 spreads over the entire face side 11a of the target object 11, and covers the face side 11a of the target object 11.

Next, while the protective film agent 12 is being supplied to the face side 11a of the target object 11, the gas 18 is supplied from the supply port of the gas supply nozzle 16 to the face side 11a of the target object 11. As a result, the gas 18 is blown against the protective film agent 12 applied along the face side 11a of the target object 11, promoting drying of the protective film agent 12. Consequently, the protective film agent 12 cures in a state of maintaining a certain thickness or more, and the protective film 23 is formed on the face side 11a of the target object 11.

A specific example of the procedure of supplying the protective film agent 12 and the gas 18 is as follows. First, while the holding table 4 holding the target object 11 is rotated at low speed (for example, 100 rpm), the protective film agent 12 is supplied to the target object 11 from the protective film agent supply nozzle 10. As a result, the protective film agent 12 is supplied to the central portion of the face side 11a of the target object 11, and flows toward the outer peripheral edge of the target object 11 by centrifugal force. In this stage, the protective film agent 12 covers only part of the face side 11a of the target object 11, but, in some cases, may reach the outer peripheral edge of the target object 11 and cover the entire face side 11a.

Thereafter, the rotational speed of the holding table 4 is increased, so that the holding table 4 is rotated at high speed. For example, the rotational speed of the holding table 4 is set to a speed equal to or higher than two times but equal to lower than 10 times the speed at the time of low-speed rotation (equal to or higher than 200 rpm but equal to or lower than 1000 rpm). As a result, the protective film agent 12 reaches the outer peripheral edge of the target object 11 by centrifugal force, and covers the entire face side 11a of the target object 11. Further, by a portion of the protective film agent 12 being removed from the face side 11a of the target object 11 by centrifugal force, the thickness of the protective film agent 12 is adjusted. Note that the rotational speed of the holding table 4 at the time of high-speed rotation may be set as appropriate according to the material of the protective film agent 12, the target value of the thickness of the protective film agent 12, and the like.

Further, supply of the gas 18 from the gas supply nozzle 16 to the target object 11 is started between the time when supply of the protective film agent 12 from the protective film agent supply nozzle 10 to the target object 11 is started and the time when the protective film agent 12 reaches the outer peripheral edge of the target object 11 (the entire face side 11a of the target object 11 is covered with the protective film agent 12). As a result, coating the face side 11a of the target object 11 with the protective film agent 12 and drying of the protective film agent 12 are carried out concurrently, speeding up the drying of the protective film agent 12.

Note that supply of the gas 18 may be started in any of the time period during which the holding table 4 is rotated at low speed, the time period during which the rotational speed of the holding table 4 is increased, or the time period during which the holding table 4 is rotated at high speed. Moreover, supply of the gas 18 may be started while the protective film agent 12 is being supplied from the protective film agent supply nozzle 10 to the target object 11 or after the supply of the protective film agent 12 from the protective film agent supply nozzle 10 is stopped.

A temperature of the gas 18 supplied from the gas supply nozzle 16 to the target object 11 is, for example, set to a temperature equal to higher than 5° C., preferably equal to or higher than 23° C., and more preferably equal to or higher than 50° C. The upper limit of the temperature of the gas 18 is set by taking into consideration the characteristics of the material of the protective film agent 12, the heat resistance of the sheet 21, and other relevant factors. Moreover, as the gas 18, dry air, gas including one of or both nitrogen and carbon dioxide, or the like is preferably used.

A flow rate of the gas 18 supplied from the gas supply nozzle 16 can be set as appropriate according to a positional relation between the target object 11 and the gas supply nozzle 16 and the like. For example, when a distance between the target object 11 and the supply port of the gas supply nozzle 16 is equal to or more than 250 mm but equal to or less than 350 mm, the flow rate of the gas 18 can be set to a rate equal to or more than 80 L/min but equal to or less than 300 L/min. Moreover, when the distance between the target object 11 and the supply port of the gas supply nozzle 16 is equal to or more than 50 mm but equal to or less than 150 mm, the flow rate of the gas 18 can be set to a rate equal to or more than 20 L/min but equal to or less than 100 L/min.

Even after the supply of the protective film agent 12 from the protective film agent supply nozzle 10 is stopped, the rotation of the holding table 4 and the supply of the gas 18 are continued for a certain period of time. Further, when the protective film agent 12 is sufficiently dried and cured, the protective film 23 having a desired thickness is formed on the face side 11a of the target object 11, and the rotation of the holding table 4 and the supply of the gas 18 are stopped.

Note that, in the above description, an example in which the gas 18 is supplied from one gas supply nozzle 16 toward a position distant from the center of the target object 11 (the left side of the center of the target object 11 in FIG. 4) has been described. Yet, the configuration of the gas supply unit 14 is not limited to the abovementioned example. For example, the gas supply unit 14 may include a nozzle that supplies gas toward the center of the target object 11, or may include two or more nozzles that supply gas to different regions in the target object 11. Further, the gas supply unit 14 may include a flat-type nozzle capable of supplying gas simultaneously to linear regions extending over a distance equal to or more than a radius but equal to or less than a diameter of the target object 11.

Further, the gas supply nozzle 16 may be configured to be movable along the horizontal direction (XY plane direction) above the target object 11. In this case, in a state in which the rotation of the holding table 4 is maintained or stopped, the gas supply nozzle 16 may be moved while the gas 18 is being supplied from the gas supply nozzle 16, allowing the gas 18 to be supplied to the entire face side 11a (protective film agent 12 side) of the target object 11.

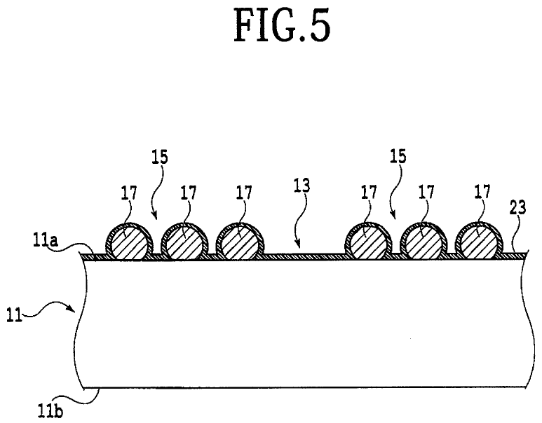

FIG. 5 is a front view, partly in cross section, illustrating the target object 11 on which the protective film 23 is formed. As described above, the plurality of protrusions 17 are formed on the face side 11a of the target object 11. When the protective film forming step S2 is carried out, the protective film 23 is formed to cover the face side of each of the plurality of protrusions 17 and protects the plurality of protrusions 17.

Here, if the gas 18 (see FIG. 4) is not supplied toward the target object 11 in the protective film forming step S2, a long period of time is taken for the protective film agent 12 (see FIG. 4) supplied to the face side 11a of the target object 11 to sufficiently dry and cure. Moreover, the protective film agent 12 not drying well may sometimes cause difficulty in forming the protective film 23 having a certain thickness or more. Further, when the protrusions 17 are provided on the target object 11, the protective film agent 12 (see FIG. 4) supplied to the protrusions 17 flows down by centrifugal force before sufficiently curing and is less likely to remain on the face side of each of the protrusions 17. As a result, the protective film 23 covering the protrusions 17 may become thin, or the distal end portions of the protrusions 17 may be exposed without being covered with the protective film 23.

In contrast, in the present embodiment, the gas 18 is blown against the protective film agent 12 supplied to the target object 11, as described above. As a result, drying of the protective film agent 12 is promoted, making it possible to form the protective film 23 having a sufficient thickness in a short period of time. Further, the protective film agent 12 can be dried to cure before flowing down from the surface of the protrusions 17, securing the protective film 23 covering the protrusions 17 to have a certain thickness or more.

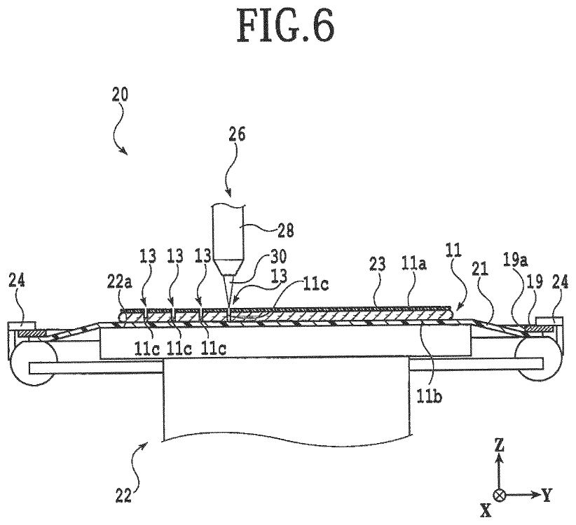

The thickness of the protective film 23 is set as appropriate according to the substance of processing performed in the dividing step S3 (see FIG. 6) described later. For example, when laser ablation processing is to be applied to the target object 11 as described later, the gas 18 is preferably supplied at the time of forming the protective film 23, to make the thickness of the portions of the protective film 23 covering the protrusions 17 equal to or more than 3 μm. This reliably protects the protrusions 17 from the processing swarf generated at the time of laser processing. The thickness of other portions of the protective film 23 can be set to be equal to or more than 20 μm, for example.

Note that the rotational speed of the holding table 4 in the second step is preferably equal to or lower than 1000 rpm. This can restrain the protective film agent 12 supplied to the target object 11 and the protrusions 17 from excessively scattering by centrifugal force and being separated from the target object 11 and the protrusions 17.

Next, the target object 11 on which the protective film 23 is formed is divided into a plurality of chips (dividing step S3). FIG. 6 is a front view, partly in cross section, illustrating the target object 11 in the dividing step S3. For example, the target object 11 is divided by laser processing using the laser processing apparatus 20.

Note that the protective film forming apparatus 2 described above (see FIG. 4) may be mounted on the laser processing apparatus 20. This makes it possible to sequentially carry out formation of the protective film 23 and laser processing of the target object 11 by the laser processing apparatus 20. In this case, the target object 11 may be held by a holding table used in common between the formation of the protective film 23 and the laser processing or may be held by different tables.

The laser processing apparatus 20 includes a holding table (chuck table) 22 that holds the target object 11. The holding table 22 has an upper surface that is a flat surface substantially parallel to the horizontal plane (XY plane) and that constitutes a holding surface 22a which holds the target object 11. The holding surface 22a is connected to a suction source (not illustrated) such as an ejector via a fluid channel (not illustrated) formed inside the holding table 22, a valve, and the like, for example.

To the holding table 22, a moving unit (not illustrated) and a rotational drive source (not illustrated) are coupled. The moving unit is, for example, configured by a moving mechanism of a ball screw type, and moves the holding table 22 along the horizontal direction (X-axis direction and Y-axis direction). The rotational drive source is configured by a motor or the like, and rotates the holding table 22 about a rotational axis substantially parallel to the Z-axis direction. Moreover, around the holding table 22, a plurality of clamps 24 for gripping and securing the frame 19 supporting the target object 11 are provided.

In addition, the laser processing apparatus 20 includes a laser application unit 26 that applies a laser beam. The laser application unit 26 includes a laser oscillator (not illustrated), such as a YAG laser, a YVO₄ laser, or a YLF laser, and a laser processing head 28 that is disposed above the holding table 22. The laser processing head 28 includes an optical system that guides, to the target object 11, a pulse-oscillating laser beam 30 emitted from the laser oscillator. The optical system includes optical elements such as a condenser lens for converging the laser beam 30 at a predetermined position. By the laser beam 30 being applied to the target object 11 from the laser processing head 28, the target object 11 is processed.

When laser processing is applied to the target object 11, first, the target object 11 is held on the holding table 22. Specifically, the target object 11 is arranged on the holding surface 22a such that the face side 11a (protective film 23 side) faces upward and the reverse side 11b (sheet 21 side) faces the holding surface 22a. In addition, the frame 19 is secured by the plurality of clamps 24. When suction force (negative pressure) of the suction source is caused to act on the holding surface 22a in this state, the target object 11 is held under suction on the holding table 22 via the sheet 21.

Next, the holding table 22 is rotated, to align a length direction of a predetermined projected dicing line 13 with the X-axis direction (processing feed direction). Moreover, the position of the holding table 22 in the Y-axis direction (indexing feed direction) is adjusted such that the region to be irradiated with the laser beam 30 is positioned on an extension of the projected dicing line 13. Further, the position of the laser processing head 28 and the location of the optical system are adjusted such that a focal point of the laser beam 30 is positioned at the same height position as the target object 11.

Then, while the laser beam 30 is being applied from the laser processing head 28, the holding table 22 is moved along the X-axis direction. As a result, the holding table 22 and the laser beam 30 move relative to each other at a predetermined speed (processing feed speed) along the X-axis direction, and the laser beam 30 is applied to the target object 11 via the protective film 23. Consequently, the target object 11 is processed along the projected dicing line 13.

Irradiation conditions of the laser beam 30 are set such that ablation processing is applied to the target object 11. Specifically, a wavelength of the laser beam 30 is set such that at least part of the laser beam 30 is absorbed by the target object 11. That is, the laser beam 30 is a laser beam absorbable by the target object 11. Moreover, other irradiation conditions of the laser beam 30 are set as appropriate such that ablation processing is appropriately applied to the target object 11. In a case where the target object 11 is a single crystal silicon wafer, for example, the irradiation conditions of the laser beam 30 can be set as follows.
Wavelength: 355 or 532 nm
Average output power: 1 to 100 W
Repetition frequency: 100 to 10000 kHz
Processing feed rate: 200 to 1000 mm/s

When the laser beam 30 is applied to the target object 11 along the projected dicing line 13, the region of the target object 11 that has been irradiated with the laser beam 30 is removed by ablation processing. As a result, a laser processing groove 11c extending from the face side 11a to the reverse side 11b of the target object 11 is formed linearly along the projected dicing line 13, and the target object 11 is divided along the projected dicing line 13. At this time, the laser beam 30 may transmit through the protective film 23 and be applied to the target object 11, or may remove the protective film 23 together with the target object 11 along the projected dicing line 13.

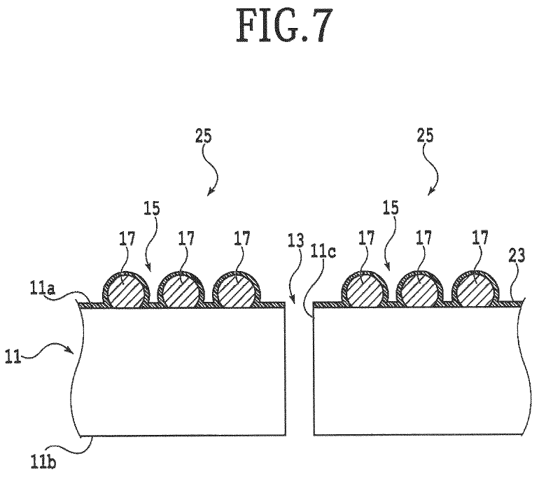

FIG. 7 is a front view, partly in cross section, illustrating the target object 11 in which the laser processing groove 11c is formed. When laser processing is applied to the target object 11, processing swarf such as a solidified melt (debris) of the target object 11 is generated at a region irradiated with the laser beam 30. Yet, the protective film 23 is formed on the face side 11a of the target object 11, and blocks processing swarf from adhering to the face side 11a of the target object 11. This can prevent the target object 11 from being contaminated by processing swarf. Particularly, in the present embodiment, the plurality of protrusions 17 provided on the face side 11a of the target object 11 are covered with the protective film 23 having a sufficient thickness. Hence, the processing swarf generated by laser processing can reliably be prevented from adhering to the protrusions 17.

Thereafter, the same procedure is repeated to form the laser processing grooves 11c in other projected dicing lines 13. When the laser processing grooves 11c are formed along all of the projected dicing lines 13, the target object 11 is divided into a plurality of chips (device chips) 25 each including the device 15 (see FIG. 1A and other relevant drawings).

Note that, in the case of dividing the target object 11 by ablation processing, the laser processing grooves 11c may be formed by application of the laser beam 30 a plurality of times along each of the projected dicing lines 13. In this case, the laser processing groove 11c extending from the face side 11a to the reverse side 11b of the target object 11 may be formed while the average output power of the laser beam 30 is reduced. This limits the heat influence on the target object 11, the devices 15, and the protrusions 17, making it less likely to cause processing failure.

While a mode of forming the laser processing grooves 11c extending from the face side 11a to the reverse side 11b of the target object 11 by application of the laser beam 30 has been described in the above description, the method of dividing the target object 11 is not limited to this example. For example, a laser processing groove having a depth less than the thickness of the target object 11 may be formed (half cutting) in the face side 11a of the target object 11 along the projected dicing line 13, by application of the laser beam 30. In this case, after the laser processing, grinding processing of grinding the reverse side 11b of the target object 11 by grindstones and thinning the target object 11 is carried out. As a result of grinding the target object 11 and exposing the laser processing grooves on the reverse side 11b of the target object 11, the target object 11 is divided into the plurality of chips 25 along the projected dicing lines 13.

Alternatively, after the target object 11 has been subjected to half cutting, external force may be applied to the target object 11, to fracture the target object 11 with the laser processing grooves being used as initiating points, and thereby divide the target object 11 along the projected dicing lines 13. As another alternative, after the target object 11 has been subjected to half cutting, an annular cutting blade may be caused to cut into a bottom of each of the laser processing grooves while being rotated, to divide the target object 11 along the projected dicing lines 13.

When dividing the target object 11 is completed, the protective film 23 is removed from the target object 11 (protective film removing step). In the protective film removing step, the protective film 23 is removed by cleaning the target object 11. For example, in a case where the protective film 23 is made of water-soluble resin, supplying cleaning water such as pure water to the target object 11 can remove the protective film 23 together with the processing swarf attached to the protective film 23.

As described above, in the protective film forming method and the chip manufacturing method according to the present embodiment, the gas 18 is supplied to the face side 11a of the target object 11 at the time of forming the protective film 23 on the target object 11. As a result, drying of the protective film agent 12 is promoted, making it possible to form the protective film 23 having a sufficient thickness in a short period of time.

Further, in the protective film forming method and the chip manufacturing method according to the present embodiment, the gas 18 is supplied while the protective film agent 12 is being supplied to the face side 11a of the target object 11 having the protrusions 17, to dry the protective film agent 12 and form the protective film 23. This makes it possible to form the protective film 23 having a thickness sufficient for covering the protrusions 17 and reliably prevent processing swarf from adhering to the protrusions 17 by the protective film 23.

Note that, in the abovementioned embodiment, the chip manufacturing method of dividing the target object 11 by laser processing has been described (see FIG. 6). Yet, the method of dividing the target object 11 on which the protective film 23 is formed is not limited to laser processing. For example, plasma etching may be applied to the target object 11, to divide the target object 11 into the plurality of chips 25 (plasma dicing).

Also in the case of dividing the target object 11 by plasma etching, first, the holding step S1 and the protective film forming step S2 described above are carried out. This forms the protective film 23 on the face side 11a of the target object 11 (see FIGS. 4 and 5). Thereafter, plasma etching gas is supplied to the target object 11 with the protective film 23 being used as a mask, and the target object 11 is divided into the plurality of chips 25 (dividing step S3).

Specifically, first, patterning of the protective film 23 is performed by removal of the protective film 23 formed on the target object 11 along the projected dicing lines 13. For example, by a laser beam being applied to the protective film 23 along the projected dicing line 13 to apply ablation processing, a region of the protective film 23 that overlaps the projected dicing line 13 is removed. This forms a groove extending from an upper surface to a lower surface of the protective film 23 along the projected dicing line 13, and exposes a region of the face side 11a of the target object 11 that overlaps the projected dicing line 13.

Note that the irradiation conditions of the laser beam are set as appropriate such that ablation processing is appropriately applied to the protective film 23. The procedure of applying the laser beam to the protective film 23 along the projected dicing line 13 is similar to that in the case of applying laser processing to the target object 11 (see FIG. 6) Yet, a focal point of the laser beam is adjusted to be positioned on the face side or inside of the protective film 23.

Next, plasma etching gas is supplied to the face side 11a of the target object 11 with the protective film 23 being used as the mask, to apply plasma etching to the target object 11. For example, plasma etching is performed with use of a plasma processing apparatus that turns the etching gas into plasma etching gas and supplies the resultant plasma etching gas to the target object 11.

The plasma processing apparatus includes a chamber (processing chamber) that houses a holding table (chuck table) that holds the target object 11 on a holding surface. Etching gas is turned into plasma etching gas inside this chamber and supplied to the target object 11 held on the holding table. Alternatively, the etching gas turned into plasma etching gas outside the chamber may be introduced into the inside of the chamber and supplied to the target object 11 held on the holding table.

For example, in a case where the target object 11 is a single crystal silicon wafer, etching gas including fluorine gas such as CF₄ and SF₆ is turned into plasma etching gas and supplied to the target object 11 by the plasma processing apparatus. Further, the etching gas that has been turned into plasma etching gas acts on the target object 11, so that plasma etching is applied to the target object 11. Yet, the components of the etching gas are selected as appropriate according to the material of the target object 11 and the protective film 23, for example.

In performing plasma etching, first, the target object 11 is held on the holding table. At this time, the target object 11 is arranged such that the face side 11a (protective film 23 side) is exposed upward and the reverse side 11b faces the holding surface of the holding table.

Next, plasma etching gas is supplied to the face side 11a of the target object 11 via the protective film 23. At this time, the etching gas is supplied to the target object 11 via the grooves of the patterned protective film 23, and acts on a region on the face side 11a of the target object 11 that overlaps the projected dicing line 13. As a result, plasma etching is applied to the target object 11 along the projected dicing line 13. Consequently, the region of the target object 11 that overlaps the projected dicing line 13 is gradually removed from the face side 11a toward the reverse side 11b, and a groove is formed along the projected dicing line 13 on the face side 11a of the target object 11.

The abovementioned plasma etching is continued until the groove formed along the projected dicing line 13 reaches the reverse side 11b of the target object 11. This forms a groove extending from the face side 11a to the reverse side 11b of the target object 11 along the projected dicing line 13, and the target object 11 is divided into the plurality of chips 25 along the projected dicing line 13.

Here, as described above, in the protective film forming method according to the present embodiment, the protective film agent 12 and the gas 18 are supplied to the target object 11, so that the protective film 23 reliably has a certain thickness or more (see FIG. 5). Hence, when plasma etching is applied to the target object 11, the face side 11a of the target object 11 can reliably be protected from the etching gas by the protective film 23.

Further, in the protective film forming method according to the present embodiment, the protective film agent 12 and the gas 18 are supplied to the target object 11, so that the protective film 23 covering the protrusions 17 reliably has a certain thickness or more. Hence, when plasma etching is applied to the target object 11, the protrusions 17 can reliably be protected from the etching gas by the protective film 23.

Besides, structures, methods, and the like according to the present embodiment can be modified and implemented as appropriate without departing from the objective scope of the present invention.

### EXAMPLES

Next, a result of evaluating the protective film formed by the protective film forming method according to the present invention is described. In this evaluation, the thickness of the protective film formed on the target object was measured to check whether drying of the protective film is promoted by supply of gas.

As the target object, a disk-shaped single crystal silicon wafer having a mirror-finished face side was used. Further, the protective film was formed with use of a protective film forming apparatus 2 (see FIG. 4) that has a configuration similar to that of the protective film forming apparatus mounted on the laser saw DFL 7160 manufactured by DISCO CORPORATION. As the gas supply nozzle, the flat air nozzle TH-F42 (nozzle width: 42 mm) manufactured by H. IKEUCHI & CO., LTD. was used. Further, the distance between the target object and the supply port of the air supply nozzle was set to 300 mm.

To form the protective film, two kinds of protective film agents A and B having different component ratios were used. The components included in the protective film agents A and B and the ratio thereof are as indicated in Table 1 below. In Table 1, PVP represents polyvinylpyrrolidone (K-90), PVA represents polyvinyl alcohol (degree of polymerization: 500, degree of saponification: 88), FA represents ferulic acid, PGME represents propylene glycol monomethyl ether, AA represents ascorbic acid, and TMP represents trimethylolpropane.

TABLE 1

| | Protective film | | Protective film | |
|---|---|---|---|---|
| | agent A | | agent B | |
| Water soluble resin | PVP | (6.5 wt %) | PVA | (8.9 wt %) |
| Light absorbent | FA | (0.3 wt %) | FA | (0.4 wt %) |
| Organic solvent | PGM | (14.0 wt %) | PGME | (15.0 wt %) |

| | | | |
|---|---|---|---|
| Additive | AA (2.5 × 10⁻³ wt %) | TMP | (11.0 wt %) |

| | |
|---|---|
| AA | (0.1 wt %) |

| | | |
|---|---|---|
| Water | (remainder) | (remainder) |
| Total | (100.0 wt %) | (100.0 wt %) |

Further, protective films were formed on a plurality of respective target objects under different conditions, and protective films according to Examples 1 through 24 and protective films according to Comparative Examples 1 through 6 were obtained. Note that the protective films according to Examples 1 through 24 were formed by supply of gas to the protective film agent A or the protective film agent B supplied to the target object. Specifically, except in Examples 20 through 24 described later, the protective film was dried by gas being supplied to the face side of the target object while the holding table was rotated (second step and third step) after the protective film agent had been supplied to the face side of the target object (first step). Meanwhile, in Comparative Examples 1 through 6, the protective film agent was dried with the holding table being rotated but no gas being supplied to the protective film agent, after the protective film agent had been applied to the face side of the target object.

Then, the thickness of each of the protective films according to Examples 1 through 24 and Comparative Examples 1 through 6 was measured. The thickness of the protective films was measured with use of F50 Automated Film Thickness Mapper manufactured by Filmetrics. Moreover, the thickness of the protective films was measured at a position with a distance of 50 mm from the outer peripheral edge of the target object.

Table 2 indicates the result of measuring the thickness of the protective films according to Examples 1 through 3 and Comparative Examples 1 and 2. In this evaluation, the thickness of the protective film immediately after the application (at the point in time when the protective film agent spread over the entire face side of the target object) and the thickness of the protective film after a predetermined period of time has passed from the time immediately after the application were measured. In Table 2 and subsequent tables, the thickness of the protective film is indicated by a unit of μm.

In Examples 1 through 3 and Comparative Examples 1 and 2, the protective film agent A was used to form the protective film, and the rotational speed of the holding table was set to 400 rpm. Further, the length of time of rotation of the holding table in Examples 1 through 3 and Comparative Examples 1 and 2 was set to 360 seconds, 300 seconds, 240 seconds, 360 seconds, and 420 seconds, respectively. When the holding table was rotated, gas (dry air) was supplied to the target object at a flow rate of 40 L/min in Examples 1 through 3, while no gas was supplied to the target object in Comparative Examples 1 and 2. Note that the dry air was generated by supply of air supplied from factory equipment to a membrane air dryer (IDG75-04-P manufactured by SMC Corporation) (the same applies in Example 4 and other subsequent examples).

TABLE 2

| | Example | Example | Example | Comparative | Comparative |
|---|---|---|---|---|---|
| | 1 | 2 | 3 | example 1 | example 2 |
| Protective | A | A | A | A | A |
| film agent | | | | | |
| Film forming | 400 rpm, | 400 rpm, | 400 rpm, | 400 rpm, | 400 rpm, |
| conditions | 360 sec. | 300 sec. | 240 sec. | 360 sec. | 420 sec. |
| Gas | 40 L/min | 40 L/min | 40 L/min | None | None |
| Immediately | 3.0 | 3.0 | 4.6 | 4.0 | 3.0 |
| after application | | | | | |
| After 2 min. | 3.0 | 2.9 | 3.4 | 2.6 | 2.2 |
| After 5 min. | — | 2.9 | 3.0 | 2.3 | 2.2 |
| After 10 min. | — | — | 2.9 | 2.3 | — |
| After 15 min. | — | — | 2.9 | — | — |

In Examples 1 through 3, even when the holding table was rotated after the application of the protective film agent A to the target object, the amount of decrease of the thickness of the protective film was small, and the protective film was maintained to have a certain thickness or more (2.9 μm or more). Meanwhile, in Comparative Examples 1 and 2, although the thickness of the protective film was equal to or more than those in Examples 1 through 3 immediately after the application of the protective film agent A to the target object, when the target object was thereafter left to stand in a state in which the rotation of the holding table was stopped, the thickness of the protective film decreased significantly (approximately 2.2 to 2.3 μm). This result has confirmed that, when gas is supplied to the target object at the time of forming the protective film, drying of the protective film agent A is promoted and formation of a thick protective film in a short period of time is facilitated.

Table 3 indicates the result of measuring the thickness of the protective films according to Examples 1, 4, and 5 and Comparative Examples 1, 3, and 4. In Examples 1, 4, and 5 and Comparative Examples 1, 3, and 4, the protective film agent A was used to form the protective film, and the rotational speed of the holding table was varied. Specifically, in Example 1 and Comparative Example 1, the holding table was rotated for 360 seconds at a rotational speed of 400 rpm (medium speed). In Example 4 and Comparative Example 3, the holding table was rotated for 300 seconds at a rotational speed of 200 rpm (low speed), thereafter for 30 seconds at a rotational speed of 400 rpm (medium speed), and then for 90 seconds at a rotational speed of 800 rpm (high speed). In Example 5 and Comparative Example 4, the holding table was rotated for 240 seconds at a rotational speed of 800 rpm (high speed). When the holding table was rotated, gas (dry air) was supplied to the target object at a flow rate of 40 L/min in Examples 1, 4, and 5, while no gas was supplied to the target object in Comparative Examples 1, 3, and 4.

TABLE 3

| | | Comparative | | Comparative | | Comparative |
|---|---|---|---|---|---|---|
| | Example 1 | example 1 | Example 4 | example 3 | Example 5 | example 4 |
| Protective | A | A | A | A | A | A |
| film agent | | | | | | |
| Film | 400 rpm, 360 sec. | | 200 rpm, 300 sec. | | 800 rpm, 240 sec. | |
| forming | | | 400 rpm, 30 sec. | | | |
| conditions | | | 800 rpm, 90 sec. | | | |
| Gas | 40 L/min | None | 40 L/min | None | 40 L/min | None |
| Immediately | 3.0 | 4.0 | 4.8 | 14.2 | 1.8 | 1.5 |
| after | | | | | | |
| application | | | | | | |
| After | 3.0 | 2.6 | 4.6 | 11.8 | 1.8 | 1.5 |
| 2 min. | | | | | | |
| After | — | 2.3 | 4.6 | 9.2 | — | — |
| 5 min. | | | | | | |
| After | — | 2.3 | — | 4.7 | — | — |
| 10 min. | | | | | | |
| After | — | — | — | 2.8 | — | — |
| 15 min. | | | | | | |
| After | — | — | — | 2.7 | — | — |
| 20 min. | | | | | | |

In Example 4, even when the holding table was rotated after the application of the protective film agent A to the target object, the amount of decrease of the thickness of the protective film was small, and the protective film was maintained to have a certain thickness or more (4.6 μm or more). Meanwhile, in Comparative Example 3, the thickness of the protective film was greater than that in Example 4 immediately after the application of the protective film agent A to the target object, but when the target object was thereafter left to stand in a state in which the rotation of the holding table was stopped, the thickness of the protective film decreased significantly (2.7 μm). Further, in Example 5 and Comparative Example 4 in which the protective film agent A was applied under such conditions that the rotation of the holding table was set to be carried out at a higher speed (800 rpm) and for a longer period of time (240 seconds) than those in Example 4 and Comparative Example 3, a large amount of the protective film agent A scattered, and the thickness of the protective film became smaller than those in Example 4 and Comparative Example 3. However, the protective film according to Example 5 was formed to be thicker than the protective film according to Comparative Example 4. The result described above has confirmed that, even when the rotational speed of the holding table is varied, drying of the protective film agent A is promoted by supply of gas and formation of a thick protective film is facilitated.

Table 4 indicates the result of measuring the thickness of the protective films according to Examples 6 and 7 and Comparative Examples 5 and 6. The film forming conditions in Example 6 and Comparative Example 5 are the same as those in Example 4 and Comparative Example 3. Further, the film forming conditions in Example 7 and Comparative Example 6 are the same as those in Example 1 and Comparative Example 1. Yet, in Examples 6 and 7 and Comparative Examples 5 and 6, the protective film agent B was used to form the protective film. Further, when the holding table was rotated, gas (dry air) was supplied to the target object at a flow rate of 70 L/min in Examples 6 and 7, while no gas was supplied to the target object in Comparative Examples 5 and 6.

TABLE 4

| | Example | Comparative | Example | Comparative |
|---|---|---|---|---|
| | 6 | example 5 | 7 | example 6 |
| Protective | B | B | B | B |
| film agent | | | | |
| Film forming | 200 rpm, 300 sec. | | 400 rpm, 360 sec. | |
| conditions | 400 rpm, 30 sec. | | | |
| | 800 rpm, 90 sec. | | | |
| Gas | 70 L/min | None | 70 L/min | None |
| Immediately | 9.8 | 8.1 | 6.6 | 4.8 |
| after application | | | | |
| After 2 min. | 9.7 | 7.0 | 6.6 | 4.7 |
| After 5 min. | 9.7 | 6.6 | — | 4.7 |
| After 10 min. | — | 6.6 | — | — |

In Example 6, the thickness of the protective film immediately after the application of the protective film agent B was greater than that in Comparative Example 5, and when the target object was thereafter left to stand in a state in which the rotation of the holding table was stopped, the protective film was maintained to have a certain thickness or more (9.7 μm or more). Similarly, in Example 7, the thickness of the protective film immediately after the application of the protective film agent B was greater than that in Comparative Example 6, and when the target object was thereafter left to stand in a state in which the rotation of the holding table was stopped, the protective film was maintained to have a certain thickness or more (6.6 μm or more). This result has confirmed that, when gas is supplied to the target object at the time of forming the protective film, drying of the protective film agent B is promoted and formation of a thick protective film is facilitated.

Table 5 indicates the result of measuring the thickness of the protective films according to Examples 6 and 8 through 12 and Comparative Example 5. In Examples 8 through 12, the protective film agent B was used to form the protective film, and the flow rate of gas (dry air) was varied. Specifically, the flow rate of gas in Examples 8 through 12 was set to 10 L/min, 30 L/min, 50 L/min, 90 L/min, and 120 L/min, respectively. Other film forming conditions in Examples 8 through 12 were similar to those in Example 6 and Comparative Example 5.

TABLE 5

| | | | | | | | Comparative |
|---|---|---|---|---|---|---|---|
| | Example 6 | Example 8 | Example 9 | Example 10 | Example 11 | Example 12 | example 5 |
| Protective | B | B | B | B | B | B | B |
| film agent | | | | | | | |
| Film | 200 rpm, 300 sec. | | | | | | |
| forming | 400 rpm, 30 sec. | | | | | | |
| conditions | 800 rpm, 90 sec. | | | | | | |
| Gas | 70 L/min | 10 L/min | 30 L/min | 50 L/min | 90 L/min | 120 L/min | None |
| Immediately | 9.8 | 8.3 | 9.2 | 10.0 | 10.5 | 10.7 | 8.1 |
| after | | | | | | | |
| application | | | | | | | |
| After | 9.7 | 8.2 | 9.1 | 9.9 | 10.4 | 10.7 | 7.0 |
| 2 min. | | | | | | | |
| After | 9.7 | 8.1 | 9.1 | 9.8 | 10.4 | — | 6.6 |
| 5 min. | | | | | | | |
| After | — | 8.1 | — | 9.8 | — | — | 6.6 |
| 10 min. | | | | | | | |

In each of Examples 6 and 8 through 12, the thickness of the protective film was greater than that in Comparative Example 5 immediately after the application of the protective film agent B, and even when the holding table was thereafter rotated, the protective film was maintained to have a certain thickness or more (8.1 μm or more). This result has confirmed that, even when the flow rate of gas is varied, drying of the protective film agent B is promoted by supply of gas and formation of a thick protective film is facilitated.

Table 6 indicates the result of measuring the thickness of the protective films according to Examples 6 and 13 through 15 and Comparative Example 5. In Examples 13 through 15, the width of the supply port of the gas supply nozzle was changed, and the flow rate of gas (dry air) was varied. Specifically, in Examples 13 through 15, a gas supply nozzle having a supply port with a width of 121 mm was used (42 mm in Example 6 and Comparative Example 5). Further, the flow rate of gas in Examples 13 through 15 was set to 40 L/min, 70 L/min, and 120 L/min, respectively. Other film forming conditions in Examples 13 through 15 were similar to those in Example 6 and Comparative Example 5.

TABLE 6

| | Example | Example | Example | Example | Comparative |
|---|---|---|---|---|---|
| | 6 | 13 | 14 | 15 | example 5 |
| Protective | B | B | B | B | B |
| film agent | | | | | |
| Film forming | 200 rpm, 300 sec. | | | | |
| conditions | 400 rpm, 30 sec. | | | | |
| | 800 rpm, 90 sec. | | | | |
| Gas | 70 L/min | 40 L/min | 70 L/min | 120 L/min | None |
| Immediately | 9.8 | 8.1 | 8.9 | 9.5 | 8.1 |
| after application | | | | | |
| After 2 min. | 9.7 | 8.0 | 8.9 | 9.5 | 7.0 |
| After 5 min. | 9.7 | 8.0 | — | — | 6.6 |
| After 10 min. | — | — | — | — | 6.6 |

In Examples 6 and 13 through 15, even when the holding table was rotated after the application of the protective film agent B to the target object, the amount of decrease of the thickness of the protective film was small, and the protective film was maintained to have a certain thickness or more (8.0 μm or more). Meanwhile, in Comparative Example 5, the thickness of the protective film was substantially the same as that in Example 13 immediately after the application of the protective film agent B to the target object, but when the target object was thereafter left to stand in a state in which the rotation of the holding table was stopped, the thickness of the protective film decreased significantly (approximately 6.6 μm). This result has confirmed that, even when the width of the supply port of the gas supply nozzle and the flow rate of the gas are varied, drying of the protective film agent B is promoted by supply of the gas and formation of a thick protective film is facilitated.

Table 7 indicates the result of measuring the thickness of the protective films according to Examples 6 and 16 through 19 and Comparative Example 5. In Examples 16 through 19, processing for drying the protective film agent B was changed. Specifically, dry air was supplied (70 L/min) in Example 6, air was supplied (70 L/min) in Example 16, nitrogen gas was supplied (70 L/min) in Example 17, dry air was supplied (70 L/min) and heating using a halogen heater was performed in Example 18, and warm air was blown in Example 19. Other film forming conditions in Examples 16 through 19 were similar to those in Example 6 and Comparative Example 5.

Note that, in Example 16, air supplied from factory equipment was supplied to the protective film agent B. In Example 17, gas (with a nitrogen concentration of 90% or more) generated by supply of the abovementioned dry air to a nitrogen gas generator (FX-780 manufactured by HAKKO corporation) was supplied to the protective film agent B. In Example 18, the target object and the protective film agent B were heated at a temperature of 30° C. to 35° C. by a halogen spot heater (HSH-7 manufactured by INFLIDGE INDUSTRIAL, LTD,.). In Example 19, warm air was supplied to the protective film agent B by use of a commercially available dryer.

TABLE 7

| | | | | | | Comparative |
|---|---|---|---|---|---|---|
| | Example 6 | Example 16 | Example 17 | Example 18 | Example 19 | example 5 |
| Protective | B | B | B | B | B | B |
| film agent | | | | | | |
| Film | 200 rpm, 300 sec. | | | | | |
| forming | 400 rpm, 30 sec. | | | | | |
| conditions | 800 rpm, 90 sec. | | | | | |
| Gas | DA | Air | Nitrogen | DA | Warm | None |
| | 70 L/min | 70 L/min | 70 L/min | 70 L/min | air | |
| | | | | Halogen | | |
| | | | | heater | | |
| Immediately | 9.8 | 9.8 | 9.9 | 10.0 | 9.0 | 8.1 |
| after | | | | | | |
| application | | | | | | |
| After | 9.7 | 9.7 | 9.8 | 10.0 | 9.2 | 7.0 |
| 2 min. | | | | | | |
| After | 9.7 | 9.7 | 9.8 | — | 9.3 | 6.6 |
| 5 min. | | | | | | |
| After | — | — | — | — | 9.3 | 6.6 |
| 10 min. | | | | | | |

In each of Examples 6 and 16 through 19, the thickness of the protective film was greater than that in Comparative Example 5 immediately after the application of the protective film agent B, and when the target object was thereafter left to stand in a state in which the rotation of the holding table was stopped, the protective film was maintained to have a certain thickness or more (9.3 μm or more). This result has confirmed that, even when means of drying the protective film agent B is changed, drying of the protective film agent B is promoted and formation of a thick protective film is facilitated.

Table 8 indicates the result of measuring the thickness of the protective films according to Examples 6 and 20 through 24 and Comparative Example 5. In Examples 20 through 24, the procedure of supplying the protective film agent B to the target object and drying the protective film agent B was changed. Further, in Examples 20 through 24, film forming conditions 1 and 2 were used for rotation of the holding table. The film forming condition 1 is a condition of rotating the holding table for five seconds at a rotational speed of 20 rpm.

Further, the film forming condition 2 is the same condition as that in the case of rotating the holding table in Example 6 and Comparative Example 5.

In Example 6, first, the protective film agent B was supplied to a central portion of the target object. Next, gas (dry air) was supplied to the target object at a flow rate of 70 L/min while the holding table was rotated under the film forming condition 2, to cover the entire face side of the target object with the protective film agent B and dry the protective film agent B.

In Example 20, first, the protective film agent B was supplied to the central portion of the target object. Next, the holding table was rotated under the film forming condition 2, to cover the entire face side of the target object with the protective film agent B. Thereafter, gas (dry air) was supplied to the target object at a flow rate of 70 L/min in a state in which rotation of the holding table was maintained, to dry the protective film agent B.

In Example 21, first, the holding table was rotated under the film forming condition 2. Next, the protective film agent B was supplied to the central portion of the target object in a state in which rotation of the holding table was maintained, to apply the protective film agent B to the entire face side of the target object. Thereafter, gas (dry air) was supplied to the target object at a flow rate of 70 L/min in a state in which rotation of the holding table was maintained, to dry the protective film agent B.

In Example 22, first, the protective film agent B was supplied to the central portion of the target object while the holding table was rotated under the film forming condition 1, to apply the protective film agent B to the entire face side of the target object. Thereafter, the holding table was rotated under the film forming condition 2, and gas (dry air) was supplied to the target object at a flow rate of 70 L/min in a state in which the rotation was maintained, to dry the protective film agent B.

In Example 23, first, the protective film agent B was supplied to the central portion of the target object while the holding table was rotated under the film forming condition 1, to apply the protective film agent B to the entire face side of the target object. Then, gas (dry air) was supplied to the target object at a flow rate of 70 L/min in a state in which rotation of the holding table was maintained, and the holding table was thereafter rotated under the film forming condition 2, to dry the protective film agent B.

In Example 24, first, the protective film agent B was supplied to the central portion of the target object while the holding table was rotated under the film forming condition 1, to apply the protective film agent B to the entire face side of the target object. Thereafter, gas (dry air) was supplied to the target object at a flow rate of 70 L/min while the holding table was rotated under the film forming condition 2, to dry the protective film agent B.

TABLE 8

| | | | | | | | Comparative |
|---|---|---|---|---|---|---|---|
| | Example 6 | Example 20 | Example 21 | Example 22 | Example 23 | Example 24 | example 5 |
| Protective | B | B | B | B | B | B | B |
| film agent | | | | | | | |
| Film | — | — | — | 20 rpm, 5 sec. | | | — |
| forming | | | | | | | |
| condition 1 | | | | | | | |
| Film | 200 rpm, 300 sec. | | | | | | |
| forming | 400 rpm, 30 sec. | | | | | | |
| condition 2 | 800 rpm, 90 sec. | | | | | | |
| Gas | 70 L/min | | | | | | None |
| Immediately | 9.8 | 9.9 | 9.9 | 9.9 | 9.9 | 9.9 | 8.1 |
| after | | | | | | | |
| application | | | | | | | |
| After 2 | 9.7 | 9.8 | 9.9 | 9.7 | 9.8 | 9.8 | 7.0 |
| min. | | | | | | | |
| After 5 | 9.7 | 9.8 | — | 9.7 | 9.8 | 9.8 | 6.6 |
| min. | | | | | | | |
| After 10 | — | — | — | — | — | — | 6.6 |
| min. | | | | | | | |

In each of Examples 6 and 20 through 24, the thickness of the protective film was greater than that in Comparative Example 5 immediately after the application of the protective film agent B, and when the target object was thereafter left to stand in a state in which the rotation of the holding table was stopped, the protective film was maintained to have a certain thickness or more (9.7 μm or more). This result has confirmed that, no matter what procedure is used to apply and dry the protective film agent B, drying of the protective film agent B is promoted by supply of gas and formation of a thick protective film is facilitated.

As described above, the evaluation in the examples has confirmed that drying of the protective film agent is promoted by supply of gas and the protective film is maintained to have a certain thickness or more. These results confirm that the protective film forming method according to the present invention can form a protective film having a sufficient thickness in a short period of time.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A protective film forming method of forming a protective film on a target object, comprising:
holding a reverse side of the target object on a holding table such that a face side of the target object is exposed; and
forming the protective film on the face side of the target object, wherein
the forming the protective film includes supplying a protective film agent in liquid form to the face side of the target object, rotating the holding table, and supplying gas to the face side of the target object.

2. The protective film forming method according to claim 1, wherein the supplying the protective film agent, the rotating the holding table, and the supplying the gas are carried out at different timings.

3. The protective film forming method according to claim 1, wherein at least two or more of the supplying the protective film agent, the rotating the holding table, and the supplying the gas are carried out concurrently.

4. The protective film forming method according to claim 1, wherein a rotational speed of the holding table is equal to or lower than 1000 rpm.

5. The protective film forming method according to claim 1, wherein the target object has protrusions on the face side.

6. The protective film forming method according to claim 5, wherein the protrusions are each a bump provided on the target object.

7. A chip manufacturing method of dividing a target object demarcated into a plurality of regions by projected dicing lines into a plurality of chips, comprising:
holding a reverse side of the target object on a holding table such that a face side of the target object is exposed;
forming a protective film on the face side of the target object; and
dividing the target object into the plurality of chips by applying a laser beam from the face side of the target object to form laser processing grooves in the face side of the object along the projected dicing lines and exposing the laser processing grooves on the reverse side of the target object, wherein
the forming the protective film includes supplying a protective film agent in liquid form to the face side of the target object, rotating the holding table, and supplying gas to the face side of the target object.

8. A chip manufacturing method of dividing a target object demarcated into a plurality of regions by projected dicing lines into a plurality of chips, comprising:
holding a reverse side of the target object on a holding table such that a face side of the target object is exposed;
forming a protective film on the face side of the target object; and
dividing the target object into the plurality of chips by supplying plasma etching gas to the target object via the protective film after removing the protective film along the projected dicing lines, wherein
the forming the protective film includes supplying a protective film agent in liquid form to the face side of the target object, rotating the holding table, and supplying gas to the face side of the target object.

9. The chip manufacturing method according to claim 7, wherein the supplying the protective film agent, the rotating the holding table, and the supplying the gas are carried out at different timings.

10. The chip manufacturing method according to claim 7, wherein at least two or more of the supplying the protective film agent, the rotating the holding table, and the supplying the gas are carried out concurrently.

11. The chip manufacturing method according to claim 7, wherein a rotational speed of the holding table is equal to or lower than 1000 rpm.

12. The chip manufacturing method according to claim 7, wherein the target object has protrusions on the face side.

13. The chip manufacturing method according to claim 12, wherein the protrusions are each a bump provided on the target object.
